(19) United States
(12) Patent Application Publication
(10) Pub. No.: US 2025/0386708 A1
(43) Pub. Date: Dec. 18, 2025

(54) DISPLAY DEVICE, METHOD OF MANUFACTURING DISPLAY DEVICE, AND ELECTRONIC APPARATUS INCLUDING DISPLAY DEVICE

(71) Applicant: Samsung Display Co., LTD., Yongin-si (KR)

(72) Inventors: Ji Hee SON, Yongin-si (KR); Hwi KIM, Yongin-si (KR); Jung Sun PARK, Yongin-si (KR); Seoul Ki LEE, Yongin-si (KR); A Reum LEE, Yongin-si (KR); Yeon Hwa LEE, Yongin-si (KR); Joon Gu LEE, Yongin-si (KR)

(73) Assignee: Samsung Display Co., LTD., Yongin-si (KR)

(21) Appl. No.: 19/018,122

(22) Filed: Jan. 13, 2025

(30) Foreign Application Priority Data
Jun. 18, 2024 (KR) 10-2024-0078970
Jul. 25, 2024 (KR) 10-2024-0098498

(51) Int. Cl. H10K 59/80; H10K 59/12; H10K 71/60; H10K 102/00

(52) U.S. Cl. CPC H10K 59/80523; H10K 59/1201; H10K 59/80524; H10K 71/60; H10K 2102/351

(57) ABSTRACT

A display device includes a substrate including a light transmitting area and a display area surrounding the light transmitting area, a low adhesive layer disposed on the substrate in a transmission window area in the light transmitting area, a first cathode disposed on the substrate in the display area, and a second cathode disposed on the first cathode, the first cathode and the second cathode being made of different materials.

### CROSS-REFERENCE TO RELATED APPLICATION(S)

This application claims priority to and benefits of Korean Patent Application No. 10-2024-0078970, filed on Jun. 18, 2024, and No. 10-2024-0098498, filed on Jul. 25, 2024, under 35 U.S.C. § 119, in the Korean Intellectual Property Office (KIPO), the entire contents of which are incorporated herein by reference.

### BACKGROUND

### 1. Technical Field

Embodiments relate to a display device, a method of manufacturing the display device, and an electronic apparatus including the display device.

### 2. Description of the Related Art

A sensor module which senses external light, such as a camera module, may be disposed at a lower end of a panel. As the sensor module is located at the lower end of the panel, studies on a stack structure, a design, and the like, which are used to increase transparency, a design, and the like, have been continued.

### SUMMARY

Embodiments provide a display device which can prevent a decrease in transparency, a method of manufacturing the display device, and an electronic apparatus including the display device.

However, embodiments are not limited to those set forth herein. The above and other embodiments will become more apparent to one of ordinary skill in the art to which the disclosure pertains by referencing the detailed description of the disclosure given below.

According to an embodiment, a display device may include a substrate including a light transmitting area and a display area surrounding the light transmitting area, a low adhesive layer disposed on the substrate in a transmission window area in the light transmitting area, a first cathode disposed on the substrate in the display area, and a second cathode disposed on the first cathode, the first cathode and the second cathode being made of different materials.

The first cathode may include ytterbium (Yb), a silver-magnesium alloy (AgMg), or a silver-aluminum alloy (AgAl).

The second cathode may include a silver-palladium-copper alloy (APC alloy) or a transparent conductive oxide (TCO).

A weight of the silver may be greater than or equal to about 90% with respect to a total weight of the APC alloy.

The TCO may include at least one of indium tin oxide (ITO), indium zinc oxide (IZO), zinc oxide (ZnO), gallium zinc oxide (GZO), aluminum zinc oxide (AZO), titanium oxide (TiO₂), and tin oxide (SnO₂).

The second cathode may be a single layer.

The second cathode may have a multi-layer structure including a first layer including the TCO, a second layer including a metal, and a third layer including the TCO.

A thickness of the second cathode may be greater than a thickness of the first cathode.

The thickness of the first cathode may be in a range of about 10 Å to about 50 Å, and the thickness of the second cathode may be in a range of about 50 Å to about 100 Å.

The second cathode may not be disposed directly on the low adhesive layer.

The first cathode may extend from the display area to the transmission window area and be disposed on the low adhesive layer.

A thickness of the first cathode overlapping the transmission window area may be less than 1% of a thickness of the first cathode overlapping the display area in a thickness direction of the substrate.

The second cathode may extend from the display area to the transmission window area and be disposed on the first cathode on the low adhesive layer.

A thickness of the second cathode overlapping the transmission window area may be greater than the thickness of the first cathode overlapping the transmission window area in a thickness direction of the substrate.

According to an embodiment, an electronic apparatus may include the display device. The electronic apparatus may be a flat panel display, a curved display, a computer monitor, a medical monitor, a television, a billboard, an indoor light, an outdoor light, a signal light, a head-up display, a fully transparent display, a partially transparent display, a flexible display, a rollable display, a foldable display, a stretchable display, a laser printer, a telephone, a mobile phone, a tablet computer, a phablet, a personal digital assistant (PDA), a wearable device, a laptop computer, a digital camera, a camcorder, a viewfinder, a micro display, a three-dimensional (3D) display, a virtual reality display, an augmented reality display, a vehicle, a video wall with multiple displays tiled together, a theater screen, a stadium screen, a phototherapy device, or a signboard.

According to an embodiment, a method of manufacturing a display device may include providing a substrate including a light transmitting area and a display area surrounding the light transmitting area, depositing a low adhesive layer on the substrate in a transmission window area in the light transmitting area, depositing a first cathode on the substrate in the display area, and depositing, on the first cathode, a second cathode, the second cathode and the first cathode being made of different materials.

The depositing of the first cathode may include depositing the first cathode by a vacuum thermal evaporation (VTE) process.

The first cathode may include ytterbium (Yb), a silver-magnesium alloy (AgMg), or a silver-aluminum alloy (AgAl).

The depositing of the second cathode may include depositing the second cathode by a damage free sputter (DFS) process.

The second cathode may include a silver-palladium-copper alloy (APC alloy) or a transparent conductive oxide (TCO).

The second cathode may be deposited indirectly on the low adhesive layer.

### BRIEF DESCRIPTION OF THE DRAWINGS

The above and other features of the disclosure will become more apparent by describing in further detail embodiments thereof with reference to the accompanying drawings, in which:

FIG. 1 is a schematic block diagram illustrating a display device in accordance with an embodiment of the disclosure.

FIGS. 2 and 3 are application examples of the display device in accordance with embodiments of the disclosure.

FIG. 4 is a plan view illustrating a display area and a light transmitting area in accordance with an embodiment of the disclosure.

FIG. 5 is a schematic diagram of an equivalent circuit of a sub-pixel disposed in the display area and a sub-pixel disposed in the light transmitting area.

FIG. 6 is a schematic cross-sectional view taken along line I-I′ shown in FIG. 4 in accordance with an embodiment of the disclosure.

FIG. 7 is a schematic cross-sectional view taken along the line I-I′ shown in FIG. 4 in accordance with an embodiment of the disclosure.

FIG. 8 is a schematic cross-sectional view of a second cathode in accordance with an embodiment of the disclosure.

FIG. 9 is a graph showing a correlation between wavelength and transparency.

FIGS. 10 to 14 are schematic cross-sectional views illustrating a method of manufacturing the display device in accordance with an embodiment of the disclosure.

FIG. 15 is a schematic block diagram illustrating an electronic device including a display device in accordance with an embodiment of the disclosure.

FIG. 16 is a schematic diagram illustrating an example where the electronic device of FIG. 15 is a smartphone.

FIG. 17 is a schematic diagram illustrating an example where the electronic device of FIG. 15 is a tablet computer.

### DETAILED DESCRIPTION OF THE EMBODIMENTS

Hereinafter, embodiments of the disclosure will be described in more detail with reference to the accompanying drawings. In the description below, only a necessary part to understand an operation according to the disclosure is described and the descriptions of other parts are omitted in order not to unnecessarily obscure subject matters of the disclosure. In addition, the disclosure is not limited to embodiments described herein, but may be embodied in various different forms. Rather, embodiments described herein are provided to thoroughly and completely describe the disclosed contents and to sufficiently transfer the ideas of the disclosure to a person of ordinary skill in the art.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Also, when an element is referred to as being “in contact” or “contacted” or the like to another element, the element may be in “electrical contact” or in “physical contact” with another element; or in “indirect contact” or in “direct contact” with another element. The technical terms used herein are used only for the purpose of illustrating a specific embodiment and not intended to limit the embodiment.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof.

In the specification and the claims, the phrase “at least one of” is intended to include the meaning of “at least one selected from the group of” for the purpose of its meaning and interpretation. For example, “at least one of A and B” may be understood to mean “A, B, or A and B.” In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.”

It will be understood that, although the terms “first”, “second,” etc. may be used herein to describe various elements, these elements should not be limited by these terms. These terms are only used to distinguish one element from another element. Thus, a “first” element discussed below could also be termed a “second” element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the exemplary term “below” can encompass both an orientation of above and below. Furthermore, the apparatus may be otherwise oriented (e.g., rotated 90 degrees or at other orientations), and, as such, the spatially relative descriptors used herein interpreted accordingly.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within +30%, 20%, 10%, 5% of the stated value.

In addition, the embodiments of the disclosure are described here with reference to schematic diagrams of ideal embodiments (and an intermediate structure) of the disclosure, so that changes in a shape as shown due to, for example, manufacturing technology and/or a tolerance may be expected. Therefore, the embodiments of the disclosure shall not be limited to the specific shapes of a region shown here, but include shape deviations caused by, for example, the manufacturing technology. The regions shown in the drawings are schematic in nature, and the shapes thereof do not represent the actual shapes of the regions of the device, and do not limit the scope of the disclosure.

Unless otherwise defined or implied herein, all terms (including technical and scientific terms) used have the same meaning as commonly understood by those skilled in the art to which this disclosure pertains. It will be further understood that terms, such as those defined in commonly used dictionaries, should be interpreted as having a meaning that is consistent with their meaning in the context of the relevant art and should not be interpreted in an ideal or excessively formal sense unless clearly defined in the specification.

Hereinafter, embodiments are described in detail with reference to the accompanying drawings.

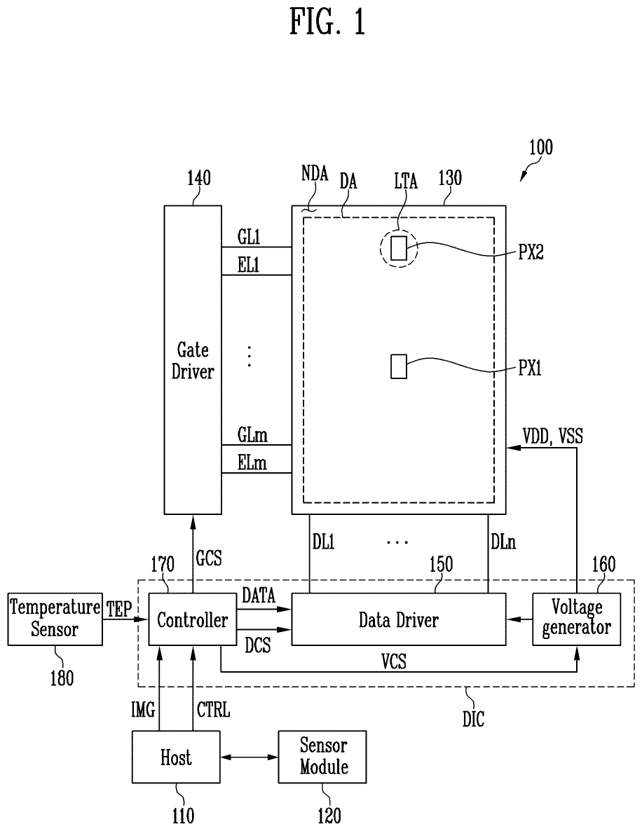

FIG. 1 is a schematic block diagram illustrating a display device in accordance with an embodiment of the disclosure.

Referring to FIG. 1, the display device 100 may include a host 110, a sensor module 120, a display panel 130, a gate driver 140, a data driver 150, a voltage generator 160, and a controller 170.

The host 110 may control an operation of the display device 100, and perform calculations or tasks. For example, the host 110 may be an Application Processor (AP), a Graphics Processing Unit (GPU), a microprocessor, a Central Processing Unit (CPU), or the like. The host 110 may control the sensor module 120 and the display panel 130. For example, the host 110 may activate the sensor module 120 to sense external light, and receive a signal or data including a sensing result from the sensor module 120. For example, the host 110 may transmit input image data IMG and a control signal CTRL to the controller 170 to display an image.

The sensor module 120 may be disposed under a light transmitting area LTA to overlap the light transmitting area LTA in a plan view. The sensor module 120 may be a module which senses external light through the light transmitting area LTA. For example, the sensor module 120 may be an image sensor module, i.e., a camera module. The image sensor module may be disposed under the display panel 130 to overlap the light transmitting area LTA in a plan view. Accordingly, the image sensor module may be designated as an Under Panel Camera (UPC). The image sensor module may photograph an external image through the light transmitting area LTA. However, the disclosure is not necessarily limited thereto. For example, the sensor module 120 may be a face recognition sensor module, a proximity sensor module, a motion sensor module, or the like. The face recognition sensor module, the proximity sensor module, the motion sensor module, or the like may be disposed under the display panel 130 to overlap the light transmitting area LTA in a plan view. Accordingly, the face recognition sensor module, the proximity sensor module, the motion sensor module, or the like may be designated as an Under Panel Sensor (UPS).

The display panel 130 may include a light transmitting area through which external light is transmitted, and a display area DA and a non-display area NDA, through which the external light is not transmitted.

The light transmitting area LTA may be disposed in the display area DA and surrounded by the display area DA in a plan view. For example, the light transmitting area LTA may be disposed at an upper center of the display area DA in a plan view. However, the disclosure is not necessarily limited thereto, and the light transmitting area LTA may be disposed at another position in the display area DA.

The display area DA may surround at least a portion of the light transmitting area LTA. The display area DA may have a closed loop including linear and/or curved sides. For example, the display area DA may have shapes such as a polygonal shape, a circular shape, a semicircular shape, or an elliptical shape in a plan view.

The non-display area NDA may be disposed at the periphery of the display area DA. The non-display area NDA may include a component for controlling first and second pixels PX1 and PX2. For example, lines connected to the first and second pixels PX1 and PX2, such as first to mth gate lines GL1 to GLm and first to nth data lines DL1 to DLm, may be disposed in the non-display area NDA.

The display panel 130 may include first pixels PX1 and second pixels PX2. The first pixels PX1 may be disposed in the display area DA. The second pixels PX2 may be disposed in the light transmitting area LTA. The first pixels PX1 and the second pixels PX2 may be connected to the gate driver 140 through the first to mth gate lines GL1 to GLm. The first pixels PX1 and the second pixels PX2 may be connected to the data driver 150 through the first to nth data lines DL1 to DLn.

Each of the first and second pixels PX1 and PX2 may include two or more sub-pixels. For example, each of the sub-pixels may generate light of a color such as red, green, blue, cyan, magenta or yellow.

The display panel 130 may selectively display an image through the light transmitting area LTA. For example, in case that the sensor module 120 operates, the display panel 130 may not display the image through the light transmitting area LTA. For example, in case that the sensor module 120 does not operate, the display panel 130 may display an image through the light transmitting area LTA. The display panel 130 may display an image through the display area DA regardless of whether the sensor module 120 operates.

The display panel 130 may have a flat display surface. However, the disclosure is not necessarily limited thereto. In another embodiment, the display panel 130 may have a partially rounded display surface. The display panel 130 may be bendable, foldable or rollable. The display panel 130 may include a material having flexible properties.

The gate driver 140 may be connected to the first and second pixels PX1 and PX2 arranged in a row direction through the first to mth gate lines GL1 to GLm. The gate driver 140 may output gate signals to the first to mth gate lines GL1 to GLm in response to a gate control signal GCS. The gate control signal GCS may include a start signal indicating a start of each frame, a horizontal synchronization signal for outputting gate signals in synchronization with timings at which data signals are applied, and the like.

In embodiments, first to mth emission control lines EL1 to ELm connected to the first and second pixels PX1 and PX2 in the row direction may be further provided. The gate driver 140 may include an emission control driver configured to control the first to mth emission control lines EL1 to ELm, and the emission control driver may operate under the control of the controller 170.

The gate driver 140 may be disposed at a side of the display panel 130. However, the disclosure is not necessarily limited thereto. In another embodiment, the gate driver 140 may be divided into two or more drivers which are physically and/or logically divided, and these drivers may be disposed at a side of the display panel 130 and another side of the display panel 130, which is opposite to the side. As such, in some embodiments, the gate driver 140 may be disposed in various forms at the periphery of the display panel 130.

The data driver 150 may be connected to the first and second pixels PX1 and PX2 arranged in a column direction through the first to nth data lines DL1 to DLn. The data driver 150 may receive image data DATA and a data control signal DCS from the controller 170. The data driver 150 may operate in response to the data control signal DCS. The data control signal DCS may include a source start pulse, a source shift clock, a source output enable signal, and the like.

The data driver 150 may transmit data signals having grayscale voltages corresponding to the image data DATA to the first to nth data lines DL1 to DLn by using voltages from the voltage generator 160. In case that a gate signal is transmitted to each of the first to mth gate lines GL1 to GLm, data signals corresponding to the image data DATA may be transmitted to the data lines DL1 to DLm. Accordingly, images may be displayed on the display panel 130.

The gate driver 140 and the data driver 150 may include complementary metal-oxide semiconductor (CMOS) circuit elements.

The voltage generator 160 may operate in response to a voltage control signal VCS from the controller 170. The voltage generator 160 may be configured to generate multiple voltages and provide the generated voltages to components of the display device 100. For example, the voltage generator 160 may be configured to generate multiple voltages by receiving an input voltage from an outside of the display device 100, adjusting the received voltage, and regulating the adjusted voltage.

The voltage generator 160 may generate a first power voltage VDD and a second power voltage VSS, and the generated first and second power voltages VDD and VSS may be provided to the first and second pixels PX1 and PX2. The first power voltage VDD may have a relatively high voltage level, and the second power voltage VSS may have a voltage level lower than the voltage level of the first power voltage VDD. However, the disclosure is not necessarily limited thereto. In another embodiment, the first power voltage VDD or the second power voltage VSS may be provided by an external device of the display device 100.

In an embodiment, the voltage generator 160 may generate various voltages. For example, the voltage generator 160 may generate an initialization voltage applied to the first and second pixels PX1 and PX2. For example, the voltage generator 160 may generate and apply a reference voltage to the first to nth data lines DL1 to DLn in a sensing operation for sensing electrical characteristics of transistors and/or light emitting elements of the first and second pixels PX1 and PX2.

The controller 170 may control overall operations of the display device 100. The controller 170 may receive the input image data IMG and the control signal CTRL from the host 110. The controller 170 may provide the gate control signal GCS, the data control signal DCS, and the voltage control signal VCS in response to the control signal CTRL.

The controller 170 may convert the input image data IMG to be suitable for the display device 100 or the display panel 130, thereby outputting the image data DATA. The controller 170 may align the input image data IMG to be suitable for the first and second pixels PX1 and PX2 in units of rows, thereby outputting the image data DATA.

Two or more of the data driver 150, the voltage generator 160, and the controller 170 may be mounted on an integrated circuit. For example, the data driver 150, the voltage generator 160, and the controller 170 may be included in a driver integrated circuit DIC. The data driver 150, the voltage generator 160, and the controller 170 may be components functionally divided in a driver integrated circuit DIC. However, the disclosure is not necessarily limited thereto. In another embodiment, at least one of the data driver 150, the voltage generator 160, and the controller 170 may be provided as a component outside of the driver integrated circuit DIC.

The display device 100 may include at least one temperature sensor 180. The temperature sensor 180 may be configured to sense a temperature at the periphery of the display panel 130 and generate temperature data TEP indicating the sensed temperature. The temperature sensor 180 may be disposed adjacent to the display panel 130 and/or the driver integrated circuit DIC.

The controller 170 may control various operations of the display device 100 in response to the temperature data TEP. The controller 170 may adjust a luminance of an image output from the display panel 130 in response to the temperature data TEP. For example, the controller 170 may control components such as the data driver 150 and/or the voltage generator 160, thereby adjusting data signals and the first and second power voltages VDD and VSS.

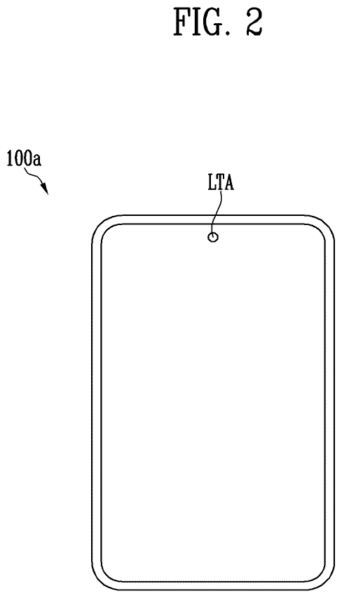

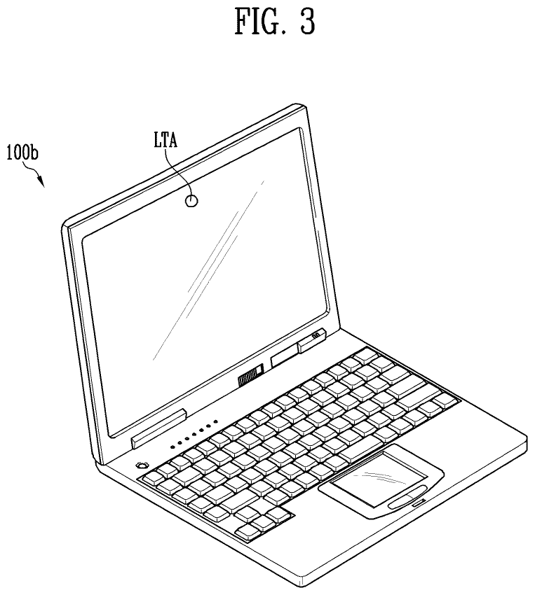

FIGS. 2 and 3 are application examples of the display device in accordance with embodiments of the disclosure.

Referring to FIG. 2, the display device 100 shown in FIG. 1 may be applied to a smartphone 100a including a light transmitting area LTA. Referring to FIG. 3, the display device 100 shown in FIG. 1 may be applied to a laptop computer 100b including a light transmitting area LTA. However, the disclosure is not necessarily limited thereto. For example, the display device 10 shown in FIG. 1 may be applied to a mobile phone, a tablet computer, a digital television (TV), a three-dimensional (3D) TV, a virtual reality (VR) device, a personal computer (PC), a home appliance, a personal digital assistant (PDA), a portable multimedia player (PMP), a digital camera, a music player, a portable game console, a navigation system, or the like.

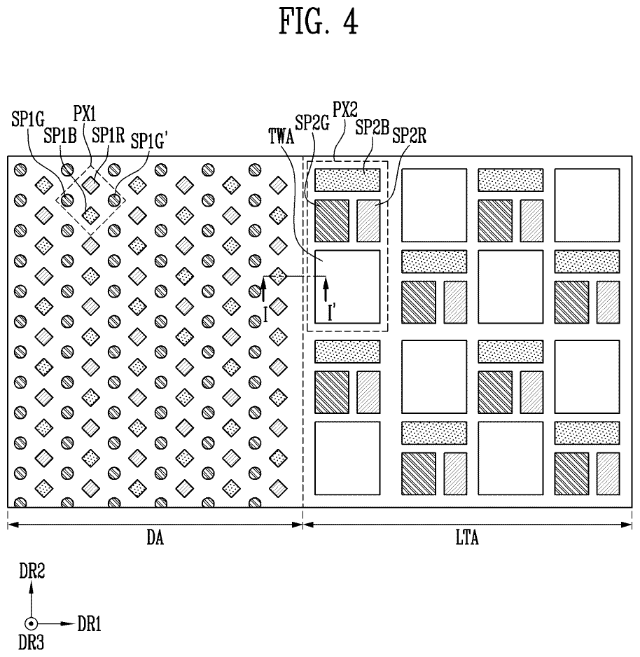

FIG. 4 is a plan view illustrating a display area and a light transmitting area in accordance with an embodiment of the disclosure. FIG. 4 schematically illustrates an embodiment of the display area DA and the light transmitting area LTA shown in FIG. 1.

Referring to FIG. 4, first pixels PX1 disposed in the display area DA and second pixels PX2 disposed in the light transmitting area LTA may have different resolutions, different arrangements, and/or different structures. For example, a Pixels Per Inch (PPI) of the light transmitting area LTA may be smaller than a PPI of the display area DA. For example, with respect to a same area, a number of the second pixels PX2 disposed in the light transmitting area LTA may be smaller than a number of the first pixels PX1 disposed in the display area DA.

Each of the first pixels PX1 may be Diamond Pixel™. For example, each of the first pixels PX1 may include a first red sub-pixel SPIR, first green sub-pixels SP1G and SP1G′, and a first blue sub-pixel SP1B. The first pixels PX1 may be arranged in a zigzag pattern in a first direction DR1 and a second direction DR2. The first direction DR1 may be a row direction, and the second direction DR2 may be a column direction. For example, the first red sub-pixels SPIR may have a diamond shape, and be arranged in a zigzag pattern in the first direction DR1 and the second direction DR2. For example, the first blue sub-pixels SP1B may have a diamond shape, and be arranged in a zigzag pattern in the first direction DR1 and the second direction DR2. For example, the first green sub-pixels SP1G and SP1G′ may have a round shape, and be arranged in a matrix pattern. However, the disclosure is not necessarily limited thereto. For example, the first red sub-pixels SPIR and the first blue sub-pixels SP1B may have a round shape. For example, the first green sub-pixels SPIG and SPIG′ may have a diamond shape. For example, the first pixels PX1 may be arranged in a matrix pattern, PENTILE™, or the like.

Each of the second pixels PX2 may include a second red sub-pixel SP2R, a second green sub-pixel SP2G, a second blue sub-pixel SP2B, and a transmission window area (or transmission window) TWA. The second pixels PX2 may be arranged in a zigzag pattern in the first direction DR1 and the second direction DR2. The second green sub-pixel SP2G and the second red sub-pixel SP2R may be arranged in the first direction DR1. The second blue sub-pixel SP2B may be arranged in the second direction DR2 from each of the second green sub-pixel SP2G and the second red sub-pixel SP2R. However, the disclosure is not necessarily limited thereto. For example, the second pixels PX2 may be arranged in a matrix pattern, PENTILE™, or the like.

The second green sub-pixel SP2G may have an area greater than an area of the second red sub-pixel SP2R, and the second blue sub-pixel SP2B may have an area greater than the area of the second green sub-pixel SP2G in a plan view. However, the disclosure is not necessarily limited thereto. For example, the second red sub-pixel SP2R and the second green sub-pixel SP2G may substantially have a same area, and the second blue sub-pixel SP2B may have an area greater than the area of each of the second red sub-pixel SP2R and the second green sub-pixel SP2G in a plan view.

The transmission window area TWA may be arranged in the second direction DR2 from each of the second green sub-pixel SP2G and the second red sub-pixel SP2R. However, the disclosure is not necessarily limited thereto. For example, a shape or arrangement of the transmission window area TWA may be variously changed according to shapes or arrangements of the second red sub-pixel SP2R, the second green sub-pixel SP2G, and the second blue sub-pixel SP2B. External light and/or light generated in the sensor module 120 (see FIG. 1) may be transmitted through the transmission window area TWA.

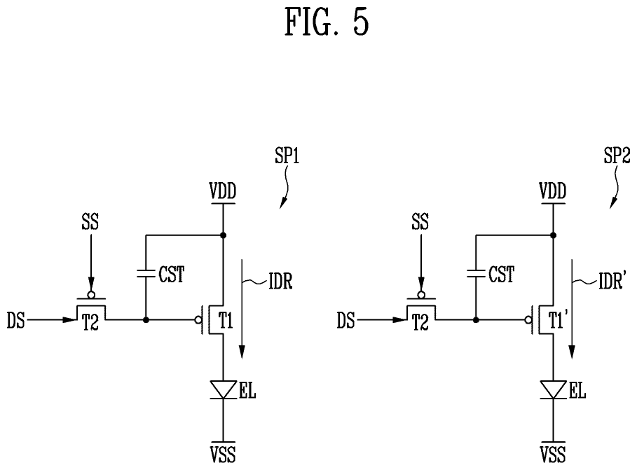

FIG. 5 is a schematic diagram of an equivalent circuit of a sub-pixel disposed in the display area and a sub-pixel disposed in the light transmitting area. FIG. 5 schematically illustrates a first sub-pixel SP1 disposed in the display area DA (see FIG. 4) and a second sub-pixel SP2 disposed in the light transmitting area LTA (see FIG. 4) according to an embodiment. The first sub-pixel SP1 may be a first red sub-pixel SPIR, each of first green sub-pixels SPIG and SP1G′, or a first blue sub-pixel SP1B shown in FIG. 4. The second sub-pixel SP2 may be a second red sub-pixel SP2R, a second green sub-pixel SP2G, or a second blue sub-pixel SP2B shown in FIG. 4.

Referring to FIG. 5, the first sub-pixel SP1 may include a scan transistor T2, a storage capacitor CST, a driving transistor T1, and a light emitting diode EL. The scan transistor T2 may transmit a data signal DS in response to a scan signal SS. The storage capacitor CST may store the data signal DS transmitted by the scan transistor T2. The driving transistor T1 may transmit a driving current IDR, based on the data signal DS stored in the storage capacitor CST. The light emitting diode EL may emit light, based on the driving current IDR flowing from a line of the first power voltage VDD to a line of the second power voltage VSS. For example, the light emitting diode EL may be an organic light emitting diode, but the disclosure is not necessarily limited thereto.

The second sub-pixel SP2 may include a scan transistor T2, a storage capacitor CST, a driving transistor T1′, and a light emitting diode EL. The scan transistor T2 and the storage capacitor CST may be the same as described above, and therefore, the detailed descriptions will be omitted. A size of the driving transistor T1′ of the second sub-pixel SP2 may be larger than a size of the driving transistor T1 of the first sub-pixel SP1. For example, a channel width of the driving transistor T1′ of the second sub-pixel SP2 may be larger than a channel width of the driving transistor T1 of the first sub-pixel SP1. Although a same data signal DS is applied to the first and second sub-pixels SP1 and SP2, a driving current IDR′ generated by the driving transistor T1′ of the second sub-pixel SP2 may be greater that the driving current IDR generated by the driving transistor T1 of the first sub-pixel SP1, and a luminance of the second sub-pixel SP2 may be greater than a luminance of the first sub-pixel SP1. Accordingly, although a resolution of the light transmitting area LTA (see FIG. 4) is lower than a resolution of the display area DA (see FIG. 4), a quality of an image displayed in the light transmitting area LTA (see FIG. 4) may be substantially equal to a quality of the image displayed in the display area DA (see FIG. 4).

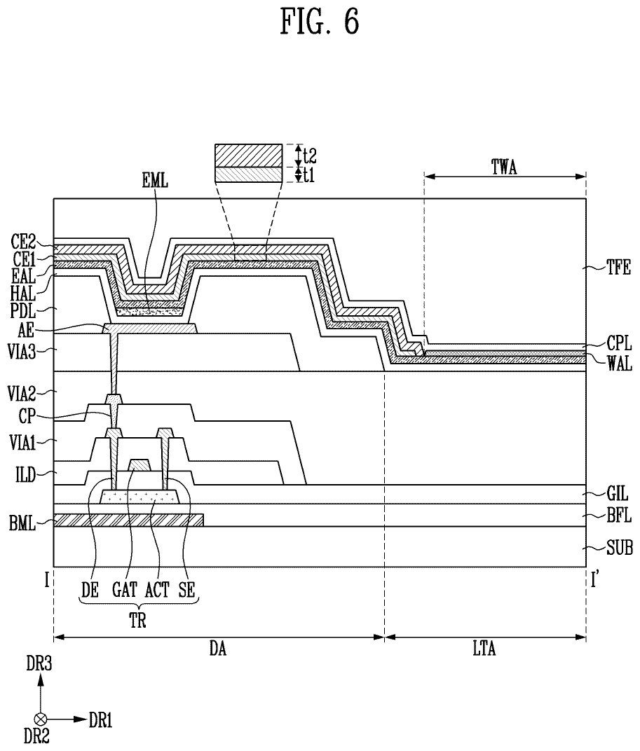

FIG. 6 is a schematic cross-sectional view taken along line I-I′ shown in FIG. 4 in accordance with an embodiment of the disclosure.

Referring to FIG. 6, a substrate SUB may include a display area DA and a light transmitting area LTA. The substrate SUB may be a silicon wafer substrate formed using a semiconductor process. The substrate SUB may include a semiconductor material suitable for forming circuit elements. For example, the substrate SUB may include silicon, germanium, and/or silicon-germanium. The substrate SUB may be provided from a bulk wafer, an epitaxial layer, a Silicon On Insulator (SOI) layer, a Semiconductor On Insulator (SeOI) layer, or the like. However, the disclosure is not necessarily limited thereto. In another embodiment, the substrate SUB may be a glass substrate or a polyimide (PI) substrate.

A bottom metal layer BML may be disposed on the substrate SUB in the display area DA. The bottom metal layer BML may include at least one of aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and copper (Cu). For example, the bottom metal layer BML may be a single layer including molybdenum, have a double-layer structure in which a molybdenum layer and a titanium layer are stacked, or have a triple-layer structure in which a titanium layer, an aluminum layer, and a titanium layer are stacked each other.

A buffer layer BFL may be disposed over the bottom metal layer BML. The buffer layer BFL may be disposed on the substrate SUB and cover the bottom metal layer BML. The buffer layer BFL may be an inorganic insulating layer including an inorganic insulating material such as silicon nitride and/or silicon oxide. The buffer layer BFL may have a single-layer or multi-layer structure including the above-described material.

An active pattern ACT may be disposed on the buffer layer BFL. The active pattern ACT may overlap the bottom metal layer BML in a third direction (or thickness direction) DR3. The active pattern ACT may include an oxide semiconductor. For example, the active pattern ACT may include indium gallium zinc oxide (IGZO) or indium tin gallium zinc oxide (ITGZO), but the disclosure is not necessarily limited thereto.

The active pattern ACT may include a channel region, and a source region and a drain region, each of which is adjacent to the channel region. The channel region may be an undoped region, and may have a low conductivity as compared to the source region and the drain region. The channel region may be a region in which a carrier (hole or electron) flows, and may be located at the center of the active pattern ACT. Each of the source region and drain region may be a doped region, and may have a high conductivity as compared to the channel region. For example, each of the source region and the drain region may be doped with an n-type dopant, but the disclosure is not necessarily limited thereto. The source region may be a region in which a carrier is supplied, and may be located at a side (e.g., a right side) of the channel region. The drain region may be a region in which a carrier supplied from the source region is discharged while passing through the channel region, and may be located at an opposite side (e.g., a left side) of the channel region.

A gate insulating layer GIL may be disposed over the active pattern ACT. The gate insulating layer GIL may be disposed on the buffer layer BFL and cover the active pattern ACT. The gate insulating layer GIL may be an inorganic insulating layer including an inorganic insulating material such as silicon oxide, silicon nitride, and/or silicon oxynitride. The gate insulating layer GIL may have a single-layer or multi-layer structure including the above-described material.

A gate electrode GAT may be disposed on the gate insulating layer GIL. The gate electrode GAT may overlap the channel region of the active pattern ACT in the third direction (or thickness direction) DR3. The gate electrode GAT may include aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and/or copper (Cu). The gate electrode GAT may be formed in a single-layer or multi-layer structure including the above-described material.

An interlayer insulating layer ILD may be disposed over the gate electrode GAT. The interlayer insulating layer ILD may be disposed on a portion of the gate insulating layer GIL and cover the gate electrode GAT. The interlayer insulating layer ILD may be an inorganic insulating layer including an inorganic insulating material such as silicon oxide, silicon nitride, and/or silicon oxynitride. The interlayer insulating layer ILD may have a single-layer or multi-layer structure including the above-described material.

A source electrode SE and a drain electrode DE may be disposed on the interlayer insulating layer ILD. The source electrode SE may be electrically connected to the source region of the active pattern ACT through a contact hole penetrating the interlayer insulating layer ILD and the gate insulating layer GIL. The drain electrode DE may be electrically connected to the drain region of the active pattern ACT through a contact hole penetrating the interlayer insulating layer ILD and the gate insulating layer GIL. The source electrode SE and the drain electrode DE may include aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and/or copper (Cu). The source electrode SE and the drain electrode DE may be formed in a single-layer or multi-layer structure including the above-described material.

The active pattern ACT, the gate electrode GAT, the source electrode SE, and the drain electrode DE, which are described above, may constitute a transistor TR. For example, the transistor TR may be the driving transistor T1 shown in FIG. 5, but the disclosure is not necessarily limited thereto.

A first via layer VIA1 may be disposed over the source electrode SE and the drain electrode DE. The first via layer VIA1 may be disposed on the interlayer insulating layer ILD and a portion of the gate insulating layer GIL and cover the source electrode SE and the drain electrode DE. The first via layer VIA1 may be an organic insulating layer including an inorganic material such as polyimide, but the disclosure is not necessarily limited thereto.

A conductive pattern CP may be disposed on the first via layer VIA1. The conductive pattern CP may be electrically connected to the drain electrode DE through a contact hole penetrating the first via layer VIA1. The conductive pattern CP may include aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and/or copper (Cu).

A second via layer VIA2 may be disposed over the conductive pattern CP. The second via layer VIA2 may be disposed on the first via layer VIA1 and the gate insulating layer GIL and cover the conductive pattern CP. The second via layer VIA2 may entirely have a flat surface. The second via layer VIA2 may include an organic insulating material, and the second via layer VIA2 may include different materials. For example, the second via layer VIA2 may be an organic insulating layer including a siloxane-based organic insulating material, but the disclosure is not necessarily limited thereto.

A third via layer VIA3 may be disposed on the second via layer VIA2. The third via layer VIA3 may entirely have a flat surface. The third via layer VIA3 and the first via layer VIA1 may include a same organic insulating material. For example, the third via layer VIA3 may be an organic insulating layer including an organic insulating material such as polyimide, but the disclosure is not necessarily limited thereto.

An anode AE may be disposed on the third via layer VIA3. The anode AE may be electrically connected to the conductive pattern CP through a contact hole penetrating the third via layer VIA3 and the second via layer VIA2. The anode AE may include a transparent conductive material such as indium tin oxide (ITO), indium zinc oxide (IZO), zinc oxide, indium gallium zinc oxide (IGZO), and/or indium tin zinc oxide (ITZO). However, the disclosure is not necessarily limited thereto. For example, the anode AE may include titanium nitride.

A pixel defining layer PDL may be disposed on a portion of the anode AE. The pixel defining layer PDL may be disposed on the third via layer VIA3 and a portion of the second via layer VIA2 and partially cover the anode AE. The pixel defining layer PDL may be disposed on the second via layer VIA2 in the display area DA. The pixel defining layer PDL may include multiple inorganic insulating layers. Each of the inorganic insulating layers may include at least one of silicon oxide and silicon nitride. For example, the pixel defining layer PDL may include first to third inorganic insulating layers which are sequentially stacked, and the first to third inorganic insulating layers may include silicon nitride, silicon oxide, and silicon nitride, respectively. However, the disclosure is not necessarily limited thereto. For example, the pixel defining layer PDL may include multiple organic insulating layers, and the organic insulating layers may include at least one of polyimide, polyamide, an acrylic resin, benzocyclobutene, and a phenolic resin.

A hole auxiliary layer HAL may be disposed on the pixel defining layer PDL and the second via layer VIA2. The hole auxiliary layer HAL may be entirely disposed throughout the display area DA and the light transmitting area LTA. The hole auxiliary layer HAL may include a hole injection layer and/or a hole transport layer, but the disclosure is not necessarily limited thereto.

A light emitting layer EML may be disposed on the hole auxiliary layer HAL. The light emitting layer EML may include an organic light emitting material, an inorganic light emitting material, an organic material and an inorganic light emitting material, a quantum dot, and/or a quantum rod, but the disclosure is not necessarily limited thereto.

An electron auxiliary layer EAL may be disposed on the light emitting layer EML and the hole auxiliary layer HAL. The electron auxiliary layer EAL may be entirely disposed throughout the display area DA and the light transmitting area LTA. The electron auxiliary layer EAL may include an electron injection layer and/or an electron transport layer, but the disclosure is not necessarily limited thereto.

A low adhesive layer WAL may be disposed on the electron auxiliary layer EAL. The low adhesive layer WAL may overlap the transmission window area TWA in the light transmitting area LTA in the third direction (or thickness direction) DR3. The low adhesive layer WAL may be a layer having weak adhesion with respect to first to second cathodes CE1 and CE2. The low adhesive layer WAL may include a material having a characteristic that the first and second cathodes CE1 and CE2 are not formed on the low adhesive layer WAL. For example, the low adhesive layer WAL may include at least one of [8-Quinolinolato Lithium]: Liq, N,N-diphenyl-N,N-bis(9-phenyl-9H-carbazol-3-yl) biphenyl-4,4′-diamine: HT01, N (diphenyl-4-yl) 9,9-dimethyl-N-(4 (9-phenyl-9H-carbazol-3-yl)phenyl)-9H-fluorene-2-amine: HT211, 2-(4-(9,10-di(naphthalene-2-yl) anthracene-2-yl)phenyl)-1-phenyl-1H-benzo-[D]imidazole: LG201, and the like. Since the first and second cathodes CE1 and CE2 are not formed on the low adhesive layer WAL, the transparency of light through the transmission window area TWA may increase.

The first cathode CE1 may be disposed on the electron auxiliary layer EAL. A thickness t1 of the first cathode CE1 may be in a range of about 10 Å to about 50 Å in the third direction DR3. Since the first cathode CE1 has weak adhesion to the low adhesive layer WAL, the first cathode CE1 may not be formed on the low adhesive layer WAL. The first cathode CE1 may include ytterbium (Yb), a silver-magnesium alloy (AgMg), and/or a silver-aluminum alloy (AgAl), but the disclosure is not necessarily limited thereto.

The second cathode CE2 may be disposed on the first cathode CE1. A thickness t2 of the second cathode CE2 may be greater than the thickness t1 of the first cathode CE1 in the third direction DR3. For example, the thickness t2 of the second cathode CE2 may be in a range of about 50 Å to about 100 Å. Since the second cathode CE2 has weak adhesion to the low adhesive layer WAL, the second cathode CE2 may not be formed on the low adhesive layer WAL. The second cathode CE2 and the first cathode CE1 may include different materials. For example, the second cathode CE2 may include a silver (Ag)-palladium (Pd)-copper (Cu) alloy (APC alloy) and/or a transparent conductive oxide (TCO). Driving efficiency may increase due to low resistance of the second cathode CE2, and optical characteristics of the display area DA may increase due to high reflectivity and transparency of the second cathode CE2. A weight of silver (Ag) may be greater than or equal to about 90% with respect to a total weight of the APC alloy. For example, the second cathode CE may include an APC alloy consisting of silver (Ag) of about 99.1 wt %, palladium (Pd) of about 0.1 wt %, and copper (Cu) of about 0.8 wt %, but the disclosure is not necessarily limited thereto. The TCO may include indium tin oxide (ITO), indium zinc oxide (IZO), zinc oxide (ZnO), gallium zinc oxide (GZO), aluminum zinc oxide (AZO), titanium oxide (TiO₂), and/or tin oxide (SnO₂). However, the disclosure is not necessarily limited thereto. The second cathode CE2 may be a single layer including the above-described material.

A capping layer CPL may be disposed on the second cathode CE2 and the low adhesive layer WAL. The capping layer CPL may be entirely disposed throughout the display area DA and the light transmitting layer LTA. The capping layer CPL may block an impurity such as moisture and/or air, introduced from the outside. The capping layer CPL may be an inorganic insulating layer including an inorganic insulating material such as silicon nitride, aluminum nitride, titanium nitride, silicon oxide, aluminum oxide, titanium oxide, silicon oxycarbide, and/or silicon oxynitride. The capping layer CPL may have a single-layer or multi-layer structure including the above-described material.

An encapsulation layer TFE may be disposed on the capping layer CPL. The encapsulation layer TFE may prevent infiltration of an impurity, moisture, and the like. The encapsulation layer TFE may have a structure in which one or more inorganic layers and one or more organic layer are alternately stacked each other. However, the disclosure is not necessarily limited thereto. For example, the encapsulation layer TFE may have a triple-layer structure in which an inorganic layer, an organic layer, and an inorganic layer are stacked each other.

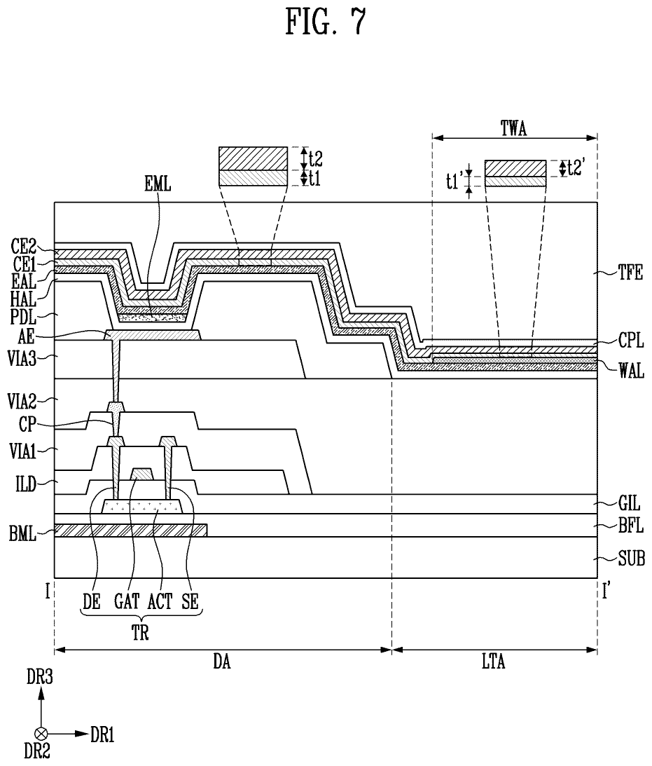

FIG. 7 is a schematic cross-sectional view taken along the line I-I′ shown in FIG. 4 in accordance with an embodiment of the disclosure. In relation to FIG. 7, descriptions of portions overlapping the portions shown in FIG. 6 will be simplified or omitted.

Referring to FIG. 7, although the low adhesive layer WAL exists, first and second cathodes CE1 and CE2 may be disposed in the transmission window area TWA.

The first cathode CE1 may extend from the display area DA to the transmission window area TWA and be disposed on the low adhesive layer WAL. The first cathode electrode CE1 may be formed thin on the low adhesive layer WAL. For example, a thickness t1′ of the first cathode CE1 disposed in (or overlapping) the transmission window area TWA may be smaller than a thickness t1 of the first cathode CE1 disposed in (or overlapping) the display area DA in the third direction DR3. For example, the thickness t1′ of the first cathode CE1 disposed in (or overlapping) the transmission window area TWA may be less than about 1% of the thickness t1 of the first cathode CE1 disposed in (or overlapping) the display area DA.

The second cathode CE2 may extend from the display area DA to the transmission window area TWA and be disposed on the first cathode CE1 on the low adhesive layer WAL. The second cathode CE2 may be formed thin on the low adhesive layer WAL. For example, a thickness t2′ of the second cathode CE2 disposed in (or overlapping) the transmission window area TWA may be smaller than a thickness t2 of the second cathode CE2 disposed in (or overlapping) the display area DA in the third direction DR3. The thickness t2′ of the second cathode CE2 in the transmission window area TWA may be greater than the thickness t1′ of the first cathode CE1 in the transmission window area TWA.

Even in case that the first and second cathodes CE1 and CE2 are disposed in the transmission window area TWA, the transparency of the second cathode CE2 including an APC alloy and/or a transparent conductive oxide (TCO) may be high, and hence the transparency of light through the transmission window area TWA may not be decreased.

As shown in FIG. 7, the second cathode CE2 may not be disposed directly on the low adhesive layer WAL in the transmission window area TWA. In other words, the second cathode CE2 may be disposed indirectly on the low adhesive layer WAL in the transmission window area TWA. Accordingly, the decrease in transparency may be prevented by preventing damage of the low adhesive layer WAL. In case that the second cathode CE2 is disposed directly on the low adhesive layer WAL in the transmission window area TWA, damage may be applied to the low adhesive layer WAL in a process of forming the second cathode CE2 on the low adhesive layer WAL, and therefore, the transparency may be decreased.

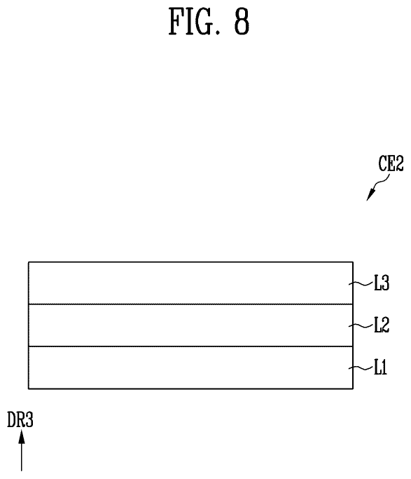

FIG. 8 is a schematic cross-sectional view of a second cathode in accordance with an embodiment of the disclosure.

Referring to FIG. 8, the second cathode CE2 may be a multi-layer having a triple-layer structure in which a first layer L1, a second layer L2, and a third layer L3 are stacked. The first layer L1 may include a transparent conductive oxide such as indium tin oxide (ITO), indium zinc oxide (IZO), zinc oxide (ZnO), gallium zinc oxide (GZO), aluminum zinc oxide (AZO), titanium oxide (TiO₂), and/or tin oxide (SnO₂). The second layer L2 may include a metal such as aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and/or copper (Cu). The third layer L3 and the first layer L1 may include a same material, but the disclosure is not necessarily limited thereto. For example, the third layer L3 and the first layer L1 may include different materials.

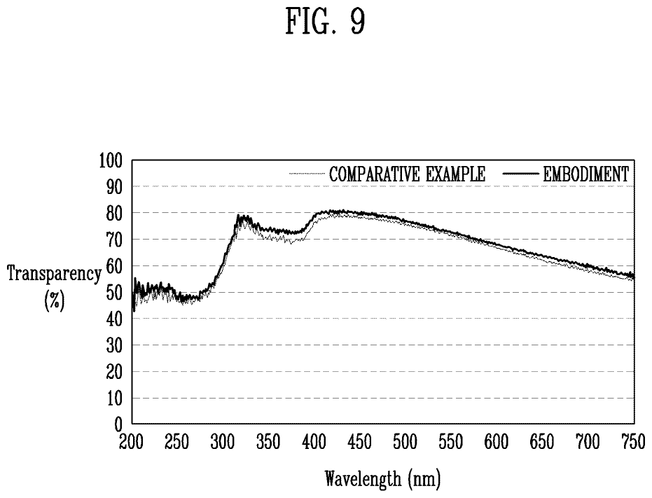

FIG. 9 is a graph showing a correlation between wavelength and transparency. FIG. 9 shows transparencies according to wavelengths of a COMPARATIVE EXAMPLE and an EMBODIMENT. The EMBODIMENT may have a structure shown in FIG. 7, i.e., a structure in which the second cathode CE2 is formed indirectly on the low adhesive layer WAL. Unlike the stacked structure shown in FIG. 7, the COMPARATIVE EXAMPLE may have a structure in which the second cathode CE2 is formed directly on the low adhesive layer WAL. For example, the COMPARATIVE EXAMPLE may have a structure in which the first cathode CE1 is omitted from the structure shown in FIG. 7.

Referring to FIG. 9, it can be seen that transparencies of the EMBODIMENT are higher than transparencies of the COMPARATIVE EXAMPLE throughout all wavelengths. This is because, while damage of the low adhesive layer WAL is prevented since the second cathode CE2 is formed indirectly on the low adhesive layer WAL in the EMBODIMENT, the transparency is decreased as the low adhesive layer WAL is damaged since the second cathode CE2 is formed directly on the low adhesive layer WAL in the COMPARATIVE EXAMPLE.

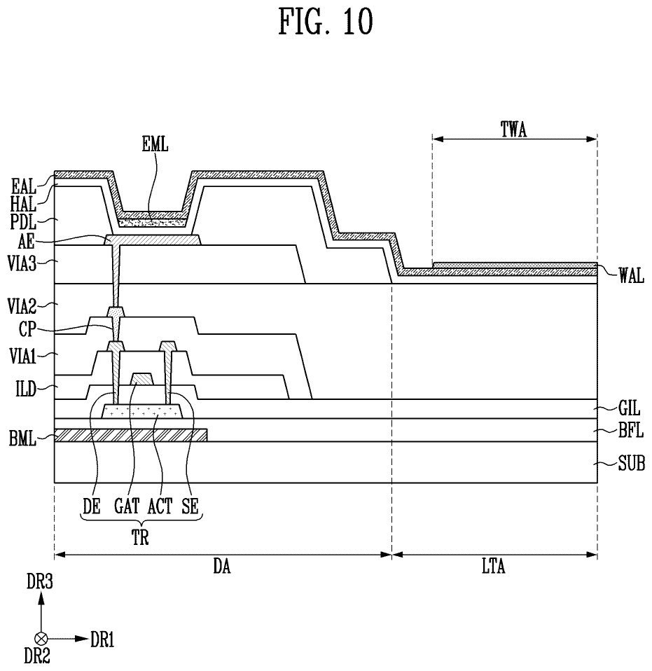

FIGS. 10 to 14 are schematic cross-sectional views illustrating a method of manufacturing the display device in accordance with an embodiment of the disclosure. In FIG. 10, it is assumed that layers except a low adhesive layer WAL are sequentially deposited with processes.

Referring to FIG. 10, a low adhesive layer WAL may be formed on the electron auxiliary layer EAL. For example, the low adhesive layer WAL may be deposited on the electron auxiliary layer EAL in the transmission window area TWA in the light transmitting area LTA, using a fine metal mask (FMM).

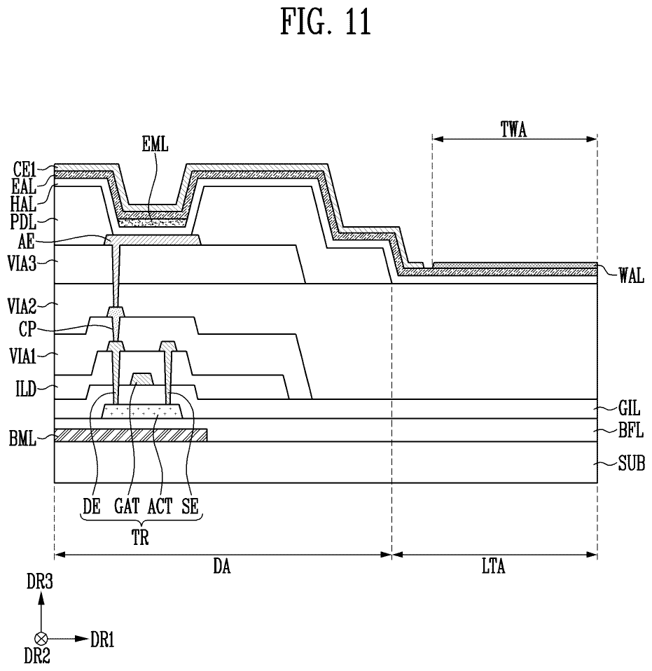

Referring to FIG. 11, a first cathode CE1 may be formed on the electron auxiliary layer EAL. The first cathode CE1 may be deposited using a metal self-patterning (MSP) method. For example, as the low adhesive layer WAL having weak adhesion to the first cathode CE1 is deposited in the transmission window area TWA, the first cathode CE1 may be not deposited in the transmission window area TWA, but may be deposited in the display area DA. The first cathode CE1 may be deposited even in the light transmitting area LTA except the transmission window area TWA. The first cathode CE1 may be deposited by a vacuum thermal evaporation (VTE) process.

The first cathode CE1 may be deposited in the transmission window area TWA according to process conditions. The first cathode CE1 may extend from the display area DA to the transmission window area TWA to be deposited thin on the low adhesive layer WAL in the transmission window area TWA (see FIG. 7). The first cathode CE1 may deposited on the low adhesive layer WAL to function to prevent damage applied to the low adhesive layer WAL.

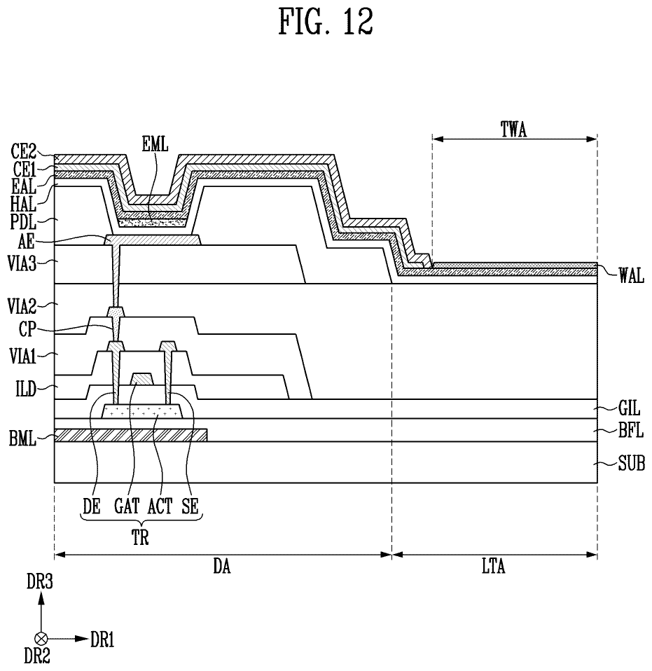

Referring to FIG. 12, a second cathode CE2 may be formed on the first cathode CE2. The second cathode CE2 may be deposited using an MSP method. For example, as the low adhesive layer WAL having weak adhesion to the second cathode CE2 is deposited in the transmission window area TWA, the second cathode CE2 may be not deposited in the transmission window area TWA, but may be deposited in the display area DA. The second cathode CE2 may be deposited even in the light transmitting area LTA except for the transmission window area TWA. The second cathode CE2 may be deposited by a damage free sputter (DFS) process.

The second cathode CE2 may be deposited in the transmission window area TWA according to process conditions. The second cathode CE2 may extend from the display area DA to the transmission window area TWA to be deposited thin on the first cathode CE1 in the transmission window area TWA (see FIG. 7). For example, the second cathode CE2 may not be deposited directly on the low adhesive layer WAL. Accordingly, damage applied to the low adhesive layer WAL in a process of depositing the second cathode CE2 may be prevented. In case that the second cathode CE2 is deposited on the low adhesive layer WAL through the DFS process, the low adhesive layer WAL may be damaged as deposition particles having high energy collide with the low adhesive layer WAL, and therefore, the transparency of light through the transmission window area TWA may be decreased.

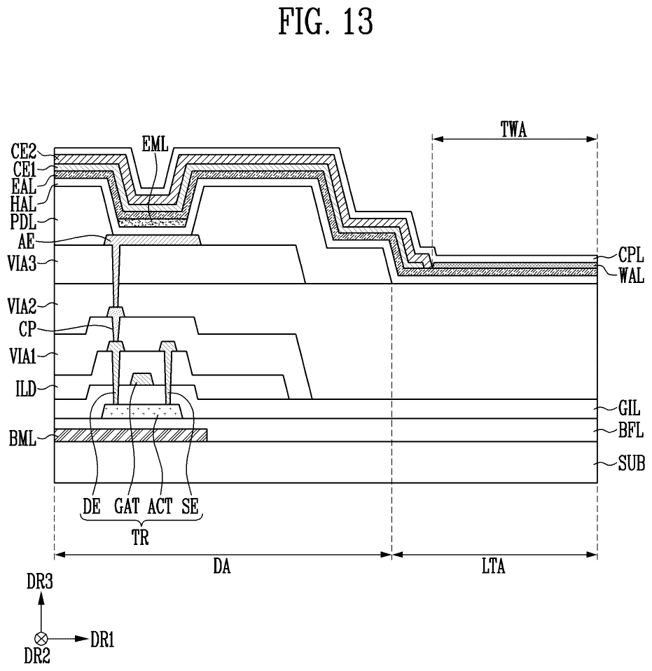

Referring to FIG. 13, a capping layer CPL may be deposited over the second cathode CE2 and the low adhesive layer WAL. The capping layer CPL may be entirely deposited throughout the display area DA and the light transmitting area LTA. As described above, in case that the first cathode CE1 and the second cathode CE2 are deposited on the low adhesive layer WAL according to process conditions, the capping layer CPL may be deposited over the second cathode CE2 in the transmission window area TWA (see FIG. 7).

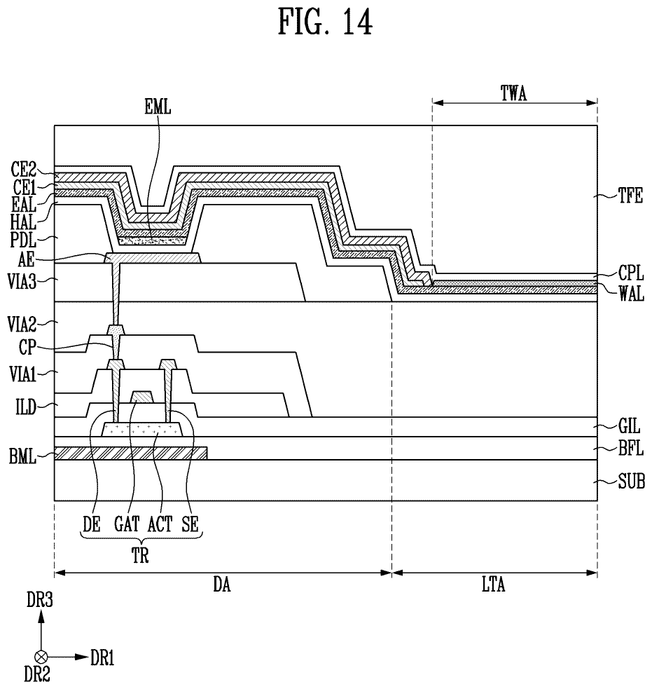

Referring to FIG. 14, an encapsulation layer TFE may be deposited on the capping layer CPL. The encapsulation layer TFE may be deposited to have an entirely flat top surface.

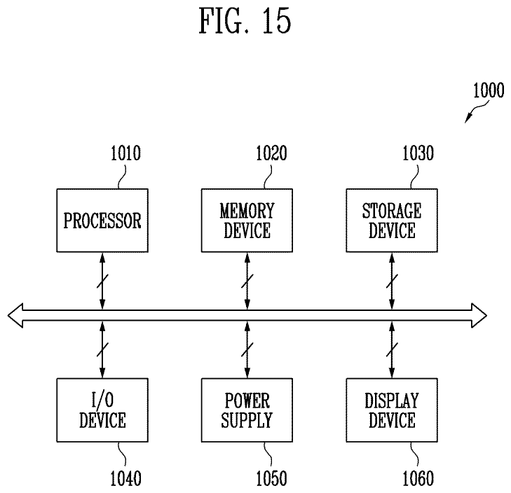

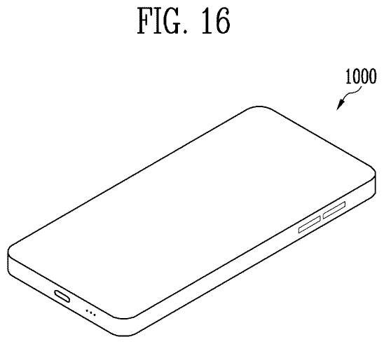

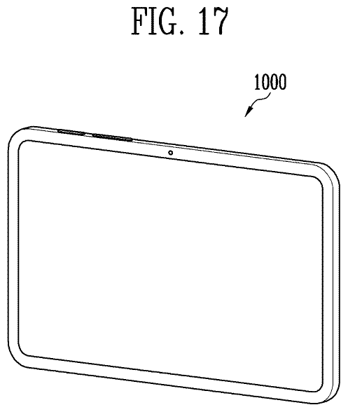

FIG. 15 is a schematic block diagram illustrating an electronic device including a display device in accordance with an embodiment of the disclosure. FIG. 16 is a schematic diagram illustrating an example where the electronic device of FIG. 15 is a smartphone. FIG. 17 is a schematic diagram illustrating an example where the electronic device of FIG. 15 is a tablet computer.

Referring to FIGS. 15 to 17, the electronic device 1000 may include a processor 1010, a memory device 1020, a storage device 1030, an input/output (I/O) device 1040, a power supply 1050, and a display device 1060. The display device 1060 may be the display device 100 of FIG. 1. The electronic device 1000 may further include various ports for communication with a video card, a sound card, a memory card, a USB device, or other systems. In an embodiment, as illustrated in FIG. 16, the electronic device 1000 may be a smartphone. In an embodiment, as illustrated in FIG. 17, the electronic device 1000 may be a tablet computer. However, the aforementioned examples are illustrative, and the electronic device 1000 is not necessarily limited to the aforementioned examples. For example, the electronic device 1000 may be a flat panel display, a curved display, a computer monitor, a medical monitor, a television, a billboard, an indoor light, an outdoor light, a signal light, a head-up display, a fully transparent display, a partially transparent display, a flexible display, a rollable display, a foldable display, a stretchable display, a laser printer, a telephone, a mobile phone, a tablet computer, a phablet, a personal digital assistant (PDA), a wearable device, a laptop computer, a digital camera, a camcorder, a viewfinder, a micro display, a three-dimensional (3D) display, a virtual reality display, an augmented reality display, a vehicle, a video wall with multiple displays tiled together, a theater screen, a stadium screen, a phototherapy device, a signboard or the like.

The processor 1010 may perform specific calculations or tasks. The processor 1010 may be the host 110 of FIG. 1. In an embodiment, the processor 1010 may include at least one of a central processing unit, an application processor, a graphic processing unit, a communication processor, an image signal processor, a controller, or the like. The processor 1010 may be connected to other components through an address bus, a control bus, a data bus, and the like. In an embodiment, the processor 1010 may be connected to an expansion bus such as a peripheral component interconnect (PCI) bus. In an embodiment, the processor 1010 may provide input image data to the display device 1060. Hence, the display device 1060 may display an image based on the input image data provided from the processor 1010.

The memory device 1020 may store data needed to perform the operation of the electronic device 1000. The memory device 1020 may function as a working memory and/or a buffer memory for the processor 1010. For example, the memory device 1020 may include one or more volatile memory devices such as a dynamic random access memory (DRAM) device, a static random access memory (SRAM) device, and a mobile DRAM device.

The storage device 1030 may store data in response to control signals or data from the processor 1010. The storage device 1030 may include one or more non-volatile storages to retain the data even when the electronic device 1000 is powered off. In some embodiments, the storage device 1030 may include a solid state drive (SSD), a hard disk drive (HDD), a CD-ROM, or the like.

The I/O device 1040 may include input devices such as a keyboard, a keypad, a touchpad, a touch screen, and a mouse, and output devices such as a speaker and a printer. In an embodiment, the display device 1060 may be integrated with the I/O device 1040.

The power supply 1050 may supply power needed to perform the operation of the electronic device 1000. For example, the power supply 1050 may include a power management integrated circuit (PMIC). In an embodiment, the power supply 1050 may supply power to the display device 1060.

The display device 1060 may display images in response to image data signals and/or control signals from the processor 1010. The display device 1060 may be connected to other components through the buses or other communication links.

The above description is an example of technical features of the disclosure, and those skilled in the art to which the disclosure pertains will be able to make various modifications and variations. Therefore, the embodiments of the disclosure described above may be implemented separately or in combination with each other.

Therefore, the embodiments disclosed in the disclosure are not intended to limit the technical spirit of the disclosure, but to describe the technical spirit of the disclosure, and the scope of the technical spirit of the disclosure is not limited by these embodiments. The protection scope of the disclosure should be interpreted by the following claims, and it should be interpreted that all technical spirits within the equivalent scope are included in the scope of the disclosure.

What is claimed is:

1. A display device comprising:
a substrate comprising a light transmitting area and a display area surrounding the light transmitting area;
a low adhesive layer disposed on the substrate in a transmission window area in the light transmitting area;
a first cathode disposed on the substrate in the display area; and
a second cathode disposed on the first cathode, the first cathode and the second cathode being made of different materials.

2. The display device of claim 1, wherein the first cathode includes ytterbium (Yb), a silver-magnesium alloy (AgMg), or a silver-aluminum alloy (AgAl).

3. The display device of claim 1, wherein the second cathode includes a silver-palladium-copper alloy (APC alloy) or a transparent conductive oxide (TCO).

4. The display device of claim 3, wherein a weight of the silver is greater than or equal to about 90% with respect to a total weight of the APC alloy.

5. The display device of claim 3, wherein the TCO includes at least one of indium tin oxide (ITO), indium zinc oxide (IZO), zinc oxide (ZnO), gallium zinc oxide (GZO), aluminum zinc oxide (AZO), titanium oxide (TiO₂), and tin oxide (SnO₂).

6. The display device of claim 3, wherein the second cathode is a single layer.

7. The display device of claim 3, wherein the second cathode has a multi-layer structure including a first layer including the TCO, a second layer including a metal, and a third layer including the TCO.

8. The display device of claim 1, wherein a thickness of the second cathode is greater than a thickness of the first cathode.

9. The display device of claim 8, wherein
the thickness of the first cathode is in a range of about 10 Å to about 50 Å, and
the thickness of the second cathode is in a range of about 50 Å to about 100 Å.

10. The display device of claim 1, wherein the second cathode is not disposed directly on the low adhesive layer.

11. The display device of claim 10, wherein the first cathode extends from the display area to the transmission window area and is disposed on the low adhesive layer.

12. The display device of claim 11, wherein a thickness of the first cathode overlapping the transmission window area is less than 1% of a thickness of the first cathode overlapping the display area in a thickness direction of the substrate.

13. The display device of claim 11, wherein the second cathode extends from the display area to the transmission window area and is disposed on the first cathode on the low adhesive layer.

14. The display device of claim 13, wherein a thickness of the second cathode overlapping the transmission window area is greater than the thickness of the first cathode overlapping the transmission window area in a thickness direction of the substrate.

15. An electronic apparatus comprising the display device of claim 1, wherein the electronic apparatus is a flat panel display, a curved display, a computer monitor, a medical monitor, a television, a billboard, an indoor light, an outdoor light, a signal light, a head-up display, a fully transparent display, a partially transparent display, a flexible display, a rollable display, a foldable display, a stretchable display, a laser printer, a telephone, a mobile phone, a tablet computer, a phablet, a personal digital assistant (PDA), a wearable device, a laptop computer, a digital camera, a camcorder, a viewfinder, a micro display, a three-dimensional (3D) display, a virtual reality display, an augmented reality display, a vehicle, a video wall with multiple displays tiled together, a theater screen, a stadium screen, a phototherapy device, or a signboard.

16. A method of manufacturing a display device, the method comprising:
providing a substrate comprising a light transmitting area and a display area surrounding the light transmitting area;
depositing a low adhesive layer on the substrate in a transmission window area in the light transmitting area;
depositing a first cathode on the substrate in the display area; and
depositing, on the first cathode, a second cathode, the second cathode and the first cathode being made of different materials.

17. The method of claim 16, wherein the depositing of the first cathode includes depositing the first cathode by a vacuum thermal evaporation (VTE) process.

18. The method of claim 17, wherein the first cathode includes ytterbium (Yb), a silver-magnesium alloy (AgMg), or a silver-aluminum alloy (AgAl).

19. The method of claim 16, wherein the depositing of the second cathode includes depositing the second cathode by a damage free sputter (DFS) process.

20. The method of claim 19, wherein the second cathode includes a silver-palladium-copper alloy (APC alloy) or a transparent conductive oxide (TCO).

21. The method of claim 16, wherein the second cathode is deposited indirectly on the low adhesive layer.
